(19) United States
(12) Patent Application Publication
(10) Pub. No.: US 2009/0120660 A1
(43) Pub. Date: May 14, 2009

(54) Electrical member and method of manufacturing a printed circuit board using the same

(75) Inventors: Dong-Jin Park, Suwon-si (KR); Chung-Woo Cho, Suwon-si (KR); Seung-Chul Kim, Cheongju-si (KR); Chang-Sup Ryu, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/081,864

(22) Filed: Apr. 22, 2008

(30) Foreign Application Priority Data
Nov. 12, 2007 (KR) 10-2007-0114878

(51) Int. Cl. H01B 3/30; H05K 3/10

(52) U.S. Cl. 174/110 R; 29/846

(57) ABSTRACT

An electrical member and a method of manufacturing a printed circuit board using the electrical member are disclosed. The method includes: forming an intaglio groove in an insulation layer, where the intaglio groove has at least one protrusion formed within; stacking a seed layer over the intaglio groove; forming a plating layer by performing electroplating over the seed layer; and forming a circuit pattern, which includes the plating layer filled in the intaglio groove, by removing a portion of the plating layer such that the insulation layer is exposed.

### CROSS-REFERENCE TO RELATED APPLICATIONS

This application claims the benefit of Korean Patent Application No. 10-2007-0114878 filed with the Korean Intellectual Property Office on Nov. 12, 2007, the disclosure of which is incorporated herein by reference in its entirety.

### BACKGROUND

1. Technical Field

The present invention relates to an electrical member and to a method of manufacturing a printed circuit board using the electrical member.

2. Description of the Related Art

With developments in electronic components, fine-lined circuit wiring is being employed in order to implement higher-density printed circuit boards. However, such wiring entails lower adhesion between the metal circuit lines and the insulating body, so that problems may occur such as the circuit lines being stripped from the insulation, etc. To respond to these problems, a method is being developed in which an intaglio groove is first processed into the insulation and then metal is filled in the intaglio groove by performing plating.

The filling of a metal by plating into an intaglio groove having a small width may not pose serious problems even when existing chemicals and processes are employed, but in cases where the width is large, such as the case illustrated in FIG. 1, it can be difficult to obtain a uniform plating thickness using existing techniques, compared to the cases for narrow intaglio grooves. Thus, it may be difficult to obtain a faultless wide circuit pattern 112 without employing a separate leveling process. When an etching process is applied to a plated circuit pattern 112, the inner portion of the intaglio groove can become uncovered, as illustrated in the drawing on the right in FIG. 1.

If a wide intaglio groove is divided to form smaller intaglio grooves, it may be possible to obtain plating thicknesses comparable to the cases for narrow intaglio grooves, but the properties as power lines or ground lines for transferring signal transferring, blocking noise, and releasing heat, etc., may be degraded. As such, there is a need for a structure which does not undermine the properties as a power line or ground line, and which does not require a separate leveling process.

### SUMMARY

An aspect of the invention is to provide a method of plating to a uniform thickness in an intaglio groove having a wide width, as well as an electrical material used for this method.

Another aspect of the invention provides a method of manufacturing a printed circuit board. The method includes: forming an intaglio groove in an insulation layer, where the intaglio groove has at least one protrusion formed within; stacking a seed layer over the intaglio groove; forming a plating layer by performing electroplating over the seed layer; and forming a circuit pattern, which includes the plating layer filled in the intaglio groove, by removing a portion of the plating layer such that the insulation layer is exposed.

The protrusion may protrude to a height lower than or equal to that of the surface of the insulation layer.

Yet another aspect of the invention provides an electrical member, which includes: an insulation layer, in which an intaglio groove is formed; and a protrusion, which protrudes inside the intaglio groove.

The protrusion can be of a height lower than or equal to that of the surface of the insulation layer. There can be multiple protrusions, where the multiple protrusions may have different heights.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a printed circuit board according to the related art.

FIG. 2 is a flowchart for a method of manufacturing a printed circuit board according to an embodiment of the invention.

FIG. 3, FIG. 4, FIG. 5, FIG. 6, and FIG. 7 are drawings representing a process flow diagram for a method of manufacturing a printed circuit board according to an embodiment of the invention.

FIG. 8 is a cross-sectional view of an electrical member according to another embodiment of the invention.

### DETAILED DESCRIPTION

The electrical member and a method of manufacturing a printed circuit board using the electrical member, according to certain embodiments of the invention, will be described below in more detail with reference to the accompanying drawings. Those components that are the same or are in correspondence are rendered the same reference numeral regardless of the figure number, and redundant explanations are omitted.

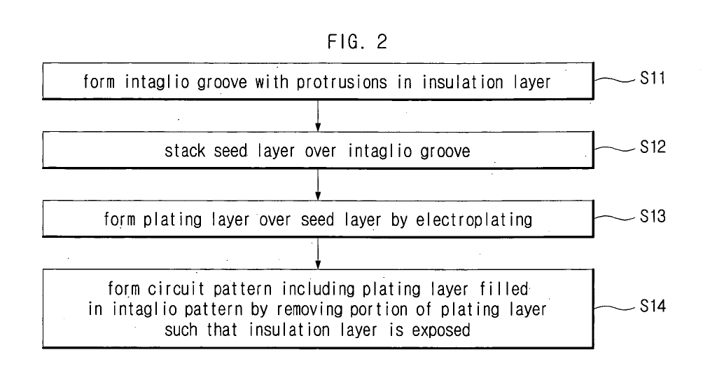

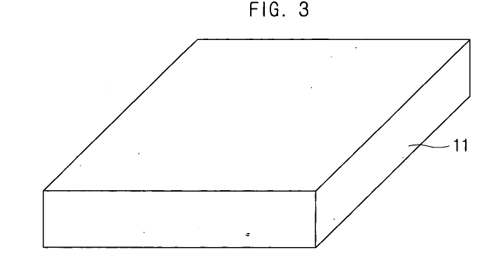

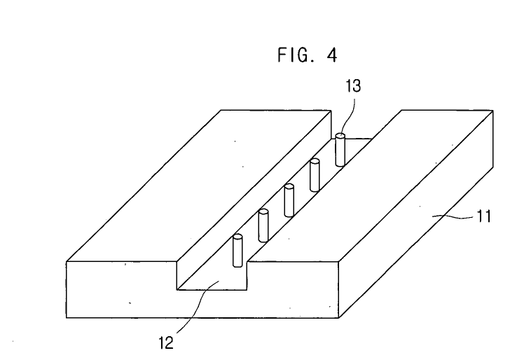

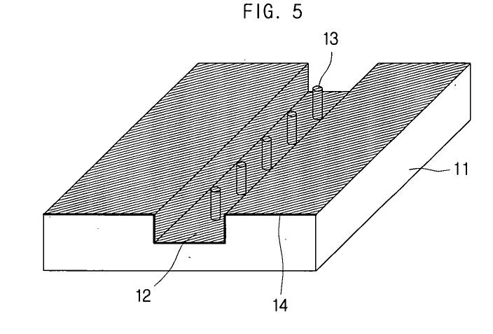

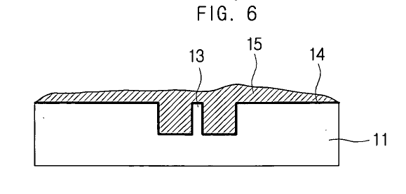

FIG. 2 is a flowchart for a method of manufacturing a printed circuit board according to an embodiment of the invention, and FIG. 3 through FIG. 7 are drawings representing a process flow diagram for a method of manufacturing a printed circuit board according to an embodiment of the invention. FIGS. 3 to 5 are perspective views, while FIGS. 6 and 7 are cross-sectional views. In FIGS. 3 to 7 are illustrated an insulation layer 11, an intaglio groove 12, protrusions 13, a seed layer 14, a plating layer 15, and a circuit pattern 16.

Operation S11 may include forming an intaglio groove, in which protrusions are formed, in an insulation layer, where FIGS. 3 and 4 illustrate examples of corresponding processes. A non-conductive electrical material, such as prepreg, can be used for the insulation layer 11.

The intaglio groove 12 can be formed by a method of irradiating laser onto the insulation layer 11. When forming the intaglio groove 12, the protrusions 13 can be formed, as shown in FIG. 4, by not removing certain areas inside the intaglio groove. The protrusions 13 will make it possible to form a plating layer to a uniform thickness over the entire area of the wide intaglio groove 12, in a subsequent plating process.

The protrusions 13 can be maintained at a height lower than or equal to the height of the surface of the insulation layer 11. One reason for this is that, if the protrusions 13 are exposed at the surface even after a circuit pattern 16 is formed, the flow of electricity may be hindered. If the insulation layer 11 is flat, the intaglio groove 12 and the protrusions 13 may be formed by a process of removing portions of the insulation layer 11, in which case the protrusions 13 cannot be higher than the height of the surface of the insulation layer 11.

Operation S12 may include stacking a seed layer over the intaglio groove, where FIG. 5 illustrates an example of a corresponding process. The seed layer 14 may facilitate the subsequent forming of the plating layer 15 by electroplating.

The seed layer 14 can be formed by electroless plating. Thus, generally, the seed layer 14 may in practice be formed not only in the intaglio groove 12 but also over the entire surface of the exposed insulation layer 11. The seed layer 14 may be stacked also over the surfaces of the protrusions 13.

Operation S13 may include forming a plating layer by performing electroplating over the seed layer, where FIG. 6 is a corresponding cross-sectional view. The insulation layer 11 can be placed in an electrolyte bath to initiate the electroplating. The plating layer 15 may be formed in portions where the seed layer 14 has been formed. To facilitate this fill plating, a brightening agent can be mixed into the electrolyte bath for the plating process. The brightening agent can increase the rate at which plating is performed.

For an intaglio groove 12 having a generally large width, the gap between the protrusions 13 and the intaglio groove 12 can be made similar state to that of an intaglio groove-having a narrow width. As a result, a generally even plating can be obtained.

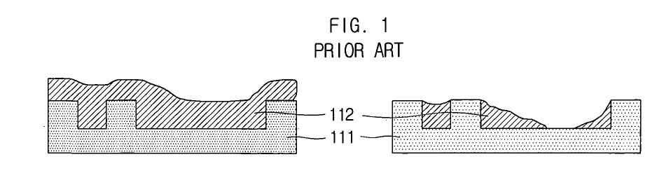

In a wide intaglio groove such as that illustrated in FIG. 1, the height of the plating layer may be lower at the center portion of the intaglio groove. In the present embodiment, however, it can be seen that, because of the protrusions 13, the plating layer 15 may readily be formed above the surface of the insulation layer 11.

Operation S14 may include removing portions of the plating layer such that the insulation layer is exposed, to form the circuit pattern, which includes the plating layer filled in the intaglio groove. FIG. 7 illustrates an example of a corresponding process.

Portions of the plating layer 15 in FIG. 6 may be removed by a process of mechanical polishing or chemical etching. As more and more of the plating layer 15 is removed from the surface of the plating layer 15, the surface of the insulation layer 11 may begin to be exposed. When the entire surface of the insulation layer 11 is exposed where the intaglio groove 12 is not formed, the plating layer 15 may remain only inside the intaglio groove 12, at which the plating layer 15 may become the circuit pattern 16, as shown in FIG. 7. While it may seem, in the cross-sectional view of FIG. 7, that the circuit pattern 16 has been cut by the protrusion 13, the protrusions 13 are in the form of islands, as illustrated in FIG. 4, so that the overall circuit pattern 16 is not cut in the horizontal direction.

As such, by performing a plating process after forming the protrusions 13 inside the intaglio groove 12, an intaglio groove 12 having a large width can be segmented by the protrusions 13 into narrower intaglio grooves. Thus, the inside of the intaglio groove 12 can be filled with the plating layer 15, enabling a plating of a uniform thickness. As a result, costs for the plating process may be reduced, and the reliability of the circuit pattern 16 may be increased.

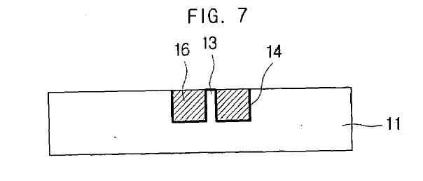

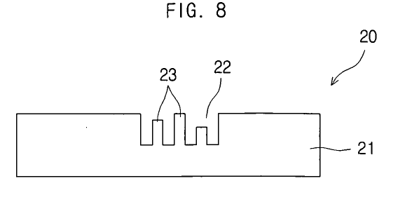

FIG. 8 is a cross-sectional view of an electrical member according to another embodiment of the invention. In FIG. 8 are illustrated an insulation layer 21, an intaglio groove 22, protrusions 23, and an electrical member 20. The electrical member 20 of this embodiment can be used as a material in manufacturing a printed circuit board.

FIG. 8 is a cross-sectional view of an electrical member 20 based on this embodiment. A perspective view of an electrical member 20 according to this embodiment may show protrusions 13 formed in an intaglio groove 12, similar to the configuration illustrated in FIG. 4. In the electrical member 20 based on this embodiment, protrusions 23 of varying sizes may be formed in the intaglio groove 22.

The intaglio groove 22 of the electrical member 20 may be the portion that will later be made into the circuit pattern by plating. As described with regards the previously disclosed embodiment, the protrusions 23 may facilitate the plating, and allow a uniform plating over the entire area of the intaglio groove 22 having a large width. The protrusions 23 may protrude in various sizes. Here, the protrusions 23 may be such that do not protrude to the outside of the insulation layer 21. A low height for the protrusions 23 can provide the advantage of lowering the resistance of the circuit pattern formed after the plating. On the other hand, a high height for the protrusions 23 can provide the advantage of allowing uniform plating, even when the width of the intaglio groove 22 is large. There can be multiple protrusions 23 used, which may have differing heights.

According to certain embodiments of the invention as set forth above, protrusions may be formed in a wide intaglio groove, to the effect that the wide intaglio groove can be divided into narrower intaglio grooves. As a result, plating may be formed uniformly over the entire intaglio groove, to form a circuit pattern with higher reliability.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board, the method comprising:
forming an intaglio groove in an insulation layer, the intaglio groove having at least one protrusion formed therein;
stacking a seed layer over the intaglio groove;
forming a plating layer by performing electroplating over the seed layer; and
forming a circuit pattern by removing a portion of the plating layer such that the insulation layer is exposed, the circuit pattern comprising the plating layer filled in the intaglio groove.

2. The method of claim 1, wherein the protrusion protrudes to a height lower than or equal to a height of a surface of the insulation layer.

3. An electrical member comprising:
an insulation layer having an intaglio groove formed therein; and
a protrusion protruding inside the intaglio groove.

4. The electrical member of claim 3, wherein the protrusion has a height lower than or equal to a height of a surface of the insulation layer.

5. The electrical member of claim 4, comprising a plurality of protrusions.

6. The electrical member of claim 5, wherein the plurality of protrusions have different heights.
